(19) United States
(12) Patent Application Publication
(10) Pub. No.: US 2026/0327844 A1
(43) Pub. Date: Oct. 22, 2026

(54) MAGNETIC NANOWIRES HAVING TERNARY ZINTL PHASE AND METHOD OF MAKING SAME

(71) Applicant: YEDA RESEARCH AND DEVELOPMENT CO. LTD., Rehovot (IL)

(72) Inventors: Haim BEIDENKOPF, Rehovot (IL); Man Suk SONG, Rehovot (IL); Lothar HOUBEN, Rehovot (IL); Hadas SHTRIKMAN, Rehovot (IL)

(21) Appl. No.: 19/491,544

(22) PCT Filed: Jun. 13, 2024
(86) PCT No.: PCT/IL2024/050589

§ 371 Date: Dec. 9, 2025

Related U.S. Application Data
(60) Provisional application No. 63/472,598, filed on Jun. 13, 2023.

(51) Int. Cl. C30B 1/10; C30B 23/02; C30B 29/40

(52) U.S. Cl. CPC C30B 1/10; C30B 23/02; C30B 29/40

(57) ABSTRACT

A nanowire having a magnetic property is disclosed. The nanowire comprising: a ternary Zintl phase of a stoichiometric formula of X₃Y₂Z₄, wherein the ternary Zintl phase is in a crystalline state; and wherein: X is selected from Eu, Ca, Sr, and Ba; Y is In or Al; and Zis As or P.

### CROSS-REFERENCE TO RELATED APPLICATIONS

The Application claims the benefit of priority of U.S. Patent Application No. 63/472,598, titled “MAGNETIC NANOWIRES HAVING TERNARY ZINTL PHASE AND METHOD OF MAKING SAME”, filed Jun. 13, 2023, the contents of which are incorporated herein by reference in their entirety.

### FIELD OF THE INVENTION

The present invention relates generally to nanowires. More specifically, the present invention relates to magnetic nanowires having a ternary Zintl phase.

### BACKGROUND OF THE INVENTION

Molecular beam epitaxy (MBE) is a process in which a thin single crystal layer is deposited on a single crystal substrate using atomic or molecular beams generated in Knudsen cells contained in an ultra-high vacuum chamber.

Growing nanowires in MBE is a challenging process in which many parameters of the individual and combined crystallographic and growth phase diagrams have to match. Therefore, the variety of compounds that can be grown as nanowires is rather limited.

Previous studies have shown that semiconductor nanowires, such as InAs nanowires can be grown using the MBE process.

However, a combination of a semiconductor and a magnetic material in the form of nanowires have not been reported.

### SUMMARY OF THE INVENTION

Some aspects of the invention are related to a nanowire, comprising: a ternary Zintl phase of a stoichiometric formula of X₃Y₂Z₄, wherein the ternary Zintl phase is in a crystalline state; and wherein:
X is selected from Eu, Ca, Sr, and Ba;
Y is In or Al; and
Z is As or P.

In some embodiments, (i) X is selected from Eu, Ca, Sr, and Ba; Y is In; and Z is As; or (ii) X is selected from Eu, Sr, and Ba; Y is In; and Z is P. In some embodiments, a crystal of said ternary Zintl phase has a Pnnm space group.

In some embodiments, the X₃Y₂Z₄ ternary Zintl phase has a crystal structure which includes subgroups of the orthorhombic crystal. In some embodiments, said Y and Z form an anionic lattice.

In some embodiments, Z occupies positions of a hexagonal lattice. In some embodiments, the nanowire has a length of between 1 to 10 μm. In some embodiments, the nanowire has a diameter of between 10 to 200 nm.

In some embodiments, said nanowire comprises a core-shell nanowire, said core-shell nanowire comprises a shell consists essentially of said ternary Zintl phase. In some embodiments, said core comprising essentially of a crystalline material of Formula YZ, having a Wurtzite crystal structure.

Some additional aspects of the invention are directed to a nanowire, comprising: a core having a Wurtzite crystal structure; and a shell comprising a ternary Zintl phase of a stoichiometric formula of X₃Y₂Z₄, wherein:
a. the core is InAs, and X is selected from Eu, Ca, Sr, or Ba, Y is In, and Z is As;
b. the core is InP, and X is selected from Eu, Sr, or Ba, Y is In, and Z is P;
c. the core is AlAs, and X is Ba, Y is Al and Z is As; or
d. the core is AIP and X is Ba, Y is Al and Z is P.

In some embodiments, the nanowire has a length of between 1 to 10 μm. In some embodiments, the nanowire has a diameter of between 10 to 200 nm. In some embodiments, the shell is a single monolayer. In some embodiments, the shell may include two or more monolayers/layers.

Some additional aspects of the invention may refer to a device, comprising: a nanowire according to any one of the embodiments disclosed herein, and two conductive layers sandwiching said nanowire. In some embodiments, said nanowire is arranged such that the longitudinal direction of said nanowire is substantially perpendicular to the surface of each conductive layer of said two conductive layers. In some embodiments, said nanowire is arranged such that the longitudinal direction of said nanowire is tilted at an angle 35° relative to the surface of each conductive layer of said two conductive layers.

In some embodiments, the device further comprises a dielectric material encompassing said nanowire while filling a volume between said two conductive layers.

Some additional aspects of the invention are directed to a method of making a nanowire, comprising: epitaxially growing a target nanowire having a stoichiometric formula YZ and a Wurtzite crystal structure; and providing a flux of gas comprising of X and Y atoms at a flux ratio of between 0.5/100 to 1.5/100 at a temperature of between 300 to 600° C.; thereby, initiating a solid-state growth of a ternary Zintl compound having a stoichiometric formula of X₃Y₂Z₄,
wherein:
   a. X is selected from Eu, Ca, Sr, or Ba, Y is In, and Z is As;
   b. X is selected from Eu, Sr, or Ba, Y is In, and Z is P; or
   c. X is Ba, Y is Al and Z is As or P.

In some embodiments, a duration of the provision of the flux is between 60 to 240 minutes. In some embodiments, the method further comprises: selecting a required thickness of the ternary Zintl compound to be grown; receiving a diameter of the target nanowire; and determining the duration of the provision of the flux based on the selected thickness and the diameter of the target nanowire.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A and 1B are an illustration and a flowchart of a method of making a nanowire according to some embodiments of the invention;

FIG. 1C is an illustration of a system for making a nanowire according to some embodiments of the invention;

FIGS. 2A, 2B, and 2C are illustrations of crystal structures of InAs, Eu₃In₂As₄, and Ba₃In₂As₄ according to some embodiments of the invention;

FIGS. 3A, 3B, and 3C are illustrations of a nanowire and cross-section in nanowires according to some embodiments of the invention;

FIG. 4 is an illustration of a device according to some embodiments of the invention;

FIG. 5 shows TEM and SEM images of Eu₃In₂As₄ crystal on InAs core, according to some embodiments of the invention;

FIG. 6 shows TEM and SEM images of a nanowire that was fully converted to Eu₃In₂AS₄, according to some embodiments of the invention; and

FIG. 7 shows TEM-EDS lattice images of atomic positions according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

Some aspects of the invention are directed to a nanowire having a ternary Zintl phase of a stoichiometric formula of X₃Y₂Z₄. Such nanowires may have magnetic properties. In a non-limiting example, intrinsically magnetic ordered crystals were grown in the form of nanowires by depositing a magnetic shell containing Eu and As on a semiconducting Wurtzite InAs core. The ternary Zintl phase was grown using topotactic (also known as topotaxial) growth. In some embodiments, indium migrates from the core to the shell and Eu migrates from the shell to the core across the rather unchanged As structure (e.g., the As acts as a skeleton).

In some embodiments, the present invention provides a magnetic compound in the form of a nanowire. In some embodiment, the present invention surprisingly provides a magnetic compound nanowire formed using a solid-state method based on a topotactic process. In some embodiments, the topotactic growth process is bi-directional, where both the core and the shell undergo a transition to a uniform structure. In some embodiment, this fabrication process strict contrast to other methodologies relating to topotactic processes where a third element dictates the structure.

In some embodiments, a nanowire comprising a ternary Zintl phase is a type of nanoscale material of a crystalline structure characterized by the Zintl phase, specifically comprising three different elements. In some embodiment, the Zintl phases may be intermetallic compounds where elements from the groups of, or rare earth metals combine with post-transition metals or metalloids.

In some embodiments, a nanowire comprising a ternary Zintl phase comprises anions that are covalently bonded networks or polyanions.

In some embodiments, a nanowire as described herein has the electronic properties of the Zintl phase. In some embodiments, a nanowire as described herein can be used in a semiconductor. In some embodiments, a nanowire as described herein may be used in thermoelectrics, electronics, or energy conversion devices.

In some embodiments, a nanowire, comprising a core having a Wurtzite crystal structure is used in optoelectronics such as but not limited to GaN in LEDs and laser diodes. In some embodiments, a nanowire, comprising a core having a Wurtzite crystal structure is used in a piezoelectric or piezomagnetic device. In some embodiments, a nanowire, comprising a core having a Wurtzite crystal structure is used in a high-power electronic device.

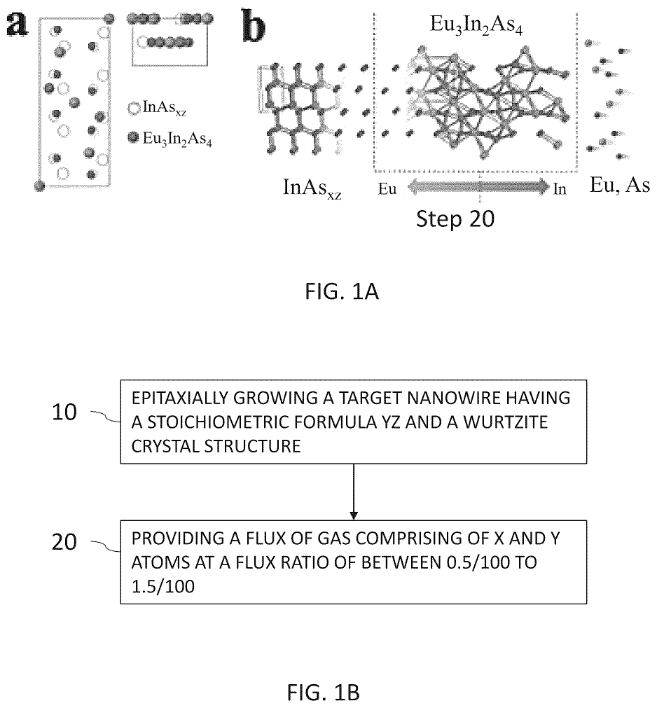

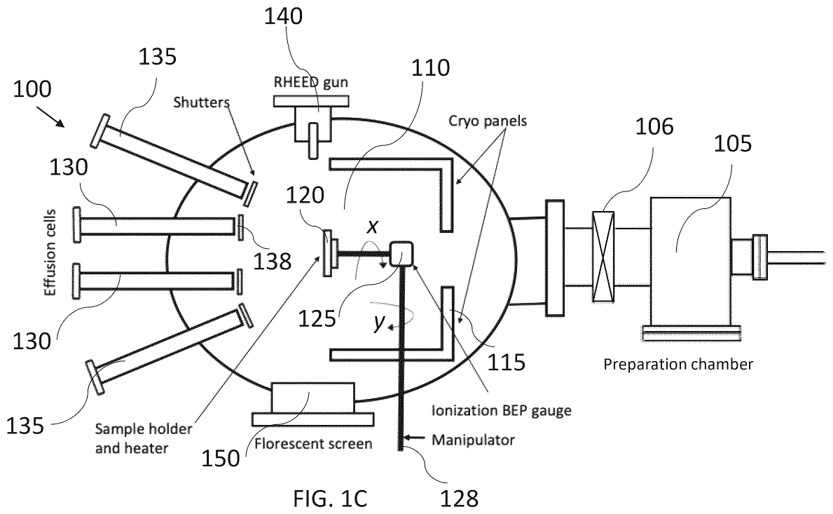

Reference is now made to FIGS. 1A and 1B which are an illustration and a flowchart of a method of making a nanowire according to some embodiments of the invention. In step 10, the method may include epitaxially growing a target nanowire having a stoichiometric formula YZ and a Wurtzite crystal structure. For example, an InAs nanowire may be epitaxially grown in a molecular beam epitaxy (MBE) system. A nonlimiting example for such a system is given and discussed with respect to FIG. 1C. In some embodiments, the target nanowire may be InP, AlAs, or AlP.

A nonlimiting example for growing InAs nanowires may include using either (001) or (111)B InAs single crystal wafers, as substrates. The substrate may be glued with indium on a moly block. In some embodiments, the moly block is pre-heated to approximately 200° C. for the removal of water.

The substrates may be inserted into a preparation chamber (e.g., chamber 105 of FIG. 1C) attached to a growth chamber (e.g., chamber 11] of FIG. 1C) where an oxide layer is first removed at approximately 650° C. In the following step, a gold layer of a thickness of approximately 1 nm (e.g., between 2 to 5 layers) is evaporated in order to create nanodroplets on the surface of the substrates. The droplets catalyze the growth of InAs nanowires.

The substrates covered by gold nanodroplets are inserted into the growth chamber. In some embodiments, As (or P) in a gas phase may be added into the growth chamber at 200 to 350° C., and any value therebetween, (e.g., 245° C. for As and higher than 285° C. for P). The added gas forms a pressure of between 1.5 to 3.5 10⁻⁸ tor, and any value therebetween, for 40 to 80 (e.g., 60) minutes (min) within the chamber.

In some embodiments, following the provision of As (or P) gas, for 40 to 80 min, (or any value therebetween) the substrate is heated up to 400 to 650° C. for balling-up and Oswald ripening the gold into catalyst droplets. Oswald ripening refers to the dissolving of the small droplets (e.g., gold droplets) and the redeposition of the small droplets onto larger droplets. For example, InAs substrate, having (001) crystallographic orientation, may be heated to 600° C. at a heating rate of 20 to 30° C./min. In another example, InAs substrate, having (111) crystallographic orientation, may be heated to 420° C. at a heating rate of 20 to 30° C./min.

After the completion of the balling-up process, the temperature of the substrates is cooled down to the growth temperature, which for InAs is between 390 to 410° C. (e.g., 400° C.). For example, the substrates may be cooled down at a cooling rate of 10 to 5° C./min. During the cooling down period (e.g., at the middle of the process) Indium (or Al) is in a gas phase may be introduced into the chamber. For example, In may be introduced at a temperature of 735° C. and Al may be introduced at a temperature of 1000° C.

The nucleation and growth of the YZ Wurtzite nanowires are monitored by electron diffraction (e.g., using reflection high-energy electron diffraction (RHEED), which detects the change from the substrate planar morphology to the nanowire morphology).

In some embodiments, the size of the gold droplets determines the diameter of the nanowires. In some embodiments, the duration of the growth (e.g., one hour) determines the length (e.g., ~1 μm) of the nanowires, for example, 1 to 10 μm.

In a nonlimiting example, As at a pressure of 9.0-6.0 10⁻⁶ Torr and In at a pressure of 1.2-7 10⁻⁷ Torr may be added during the growth phase, at a flux ratio of typically about 100 As/In. The flux ratio determines the aspect ratio of the wire.

In step 20 as schematically illustrated in FIG. 1A (b), the method may include providing a flux of gas comprising of X and Y atoms at a flux ratio of between 0.5/100 to 1.5/100 and at a temperature of between 300 to 600° C.. Thereby initiating, a solid-state growth of a ternary Zintl compound. The ternary Zintl compound may have a stoichiometric formula of X₃Y₂Z₄.

In some embodiments, X is selected from Eu, Ca, Sr, or Ba, Y is In, and Z is As. In some embodiments, X is selected from Eu, Sr, or Ba, Y is In, and Z is P. In some embodiments, X is Ba, Y is Al and Z is As or P.

In a nonlimiting example, X is Eu and a flux of Eu at a pressure of 2.0-8 10⁻⁸ Torr is added to the chamber at a temperature of 450° C.. Simultaneously, When the provision is stopped, the As pressure is kept at 9.0-6 10⁻⁶ Torr. The result is a deposited shell of XZ (e.g., EuAs, Eu₂As₃, etc.) coating the InAs nanowire.

The EuAs coating is evaporated at a rate of ~25 nm per hour while the substrate temperature is in the range of 370 to 440° C., for example, at 420° C.. Evaporation time may be between 1 to 4 hours.

At the end of the process, the X (Eu) flux is terminated and the substrate carrying the nanowires is cooled down while As is still streamed/flowed until the temperature drops below 300° C., at which the As provision is terminated.

In some embodiments, the disclosed process triggers diffusion of Y (e.g., In) from the YZ (e.g., InAs) core and X (e.g., Eu) from the deposited XZ shell to form of X₃Y₂Z₄ (e.g., Eu₃In₂As₄) crystal via a topotactic process. In this process, X and Z atoms exchange positions while the Y atoms maintain their original framework in the YZ original single crystal. The Z atoms form a hexagonal framework in the template (the original YZ Wurtzite single crystal) and the target phase (the X₃Y₂Z₄ phase). Therefore, the hexagonal Z framework may be considered as a skeleton for both the YZ and the X₃Y₂Z₄ phases. Such growth, in which one element dictates the structure of a compound is known in the art as the topotactic exchange process.

In some embodiments, the solid-state conversion in the topotactic process occurs when additional As is evaporated on the single crystal YZ (e.g. InAs) nanowires, in the presence of a strong electropositive element, for example, Europium. Although only Eu and As are provided during the topotactic process, Y atoms (e.g., In) participate in the diffusion/conversion process that results in the formation of the X₃Y₂Z₄ phase. A nonlimiting example of a topotactic process of the Eu₃In₂As₄ crystal from InAs is shown in FIG. 1A(a). In the topotactic process, Eu₃In₂As₄ overlaid with unit cells of InAs such that the As lattice remains the same, as discussed hereinbelow.

In some embodiments, the method may further include selecting a required thickness of the ternary Zintl compound to be grown and receiving a diameter of the target nanowire. For example, the diameter of the YZ nanowire may be between 10 to 200 nm, for example, 30 nm, 50 nm, 80 nm, 100 nm, 150 nm, 180 nm, 200 nm or any value therebetween. In another example, the shell is 1 monolayer or more, for example, 5, 10, 50, 100, 150 or more monolayers. As used herein, a monolayer comprises a single layer of the ternary Zintl unit cells. In one embodiment, a plurality of monolayers or layers comprises 2 or more monolayers/layers wherein each monolayer/layer comprises a single layer of the ternary Zintl unit cells.

In some embodiments, the method may include determining the duration of the provision of the flux based on the selected thickness and the diameter of the target nanowire. For example, the duration of the provision of the fluxes may be between 60 to 240 minutes.

Reference is now made to FIG. 1C which is 1C is an illustration of a nonlimiting example of a system for making a nanowire according to some embodiments of the invention. A molecular beam epitaxy (MBE) system 100 (e.g., a Riber-32™) may include a preparation chamber 105 at which a sample may undergo several reparation processes, such as but not limited to, oxidation layer removal, metal layer/droplets depositions and the like. The preparation chamber may be held under a controlled atmosphere, such as, vacuum and may be connected to a growth chamber 110 via valve 106.

Growth chamber 110 of system 100 may include an ultra-high-vacuum (UHV) system (not illustrated) and cryogenic panels 115 for ensuring UHV inside chamber 110 throughout the growth phase. UHV is defined as an atmosphere having a pressure smaller than 1.0×10⁻⁷ Pa; 1.0×10⁻⁹ mbar; or 7.5×10⁻¹⁰ Torr.

Growth chamber 110 of system 100 may house a sample/target holder and heater 120 located substantially in the middle of chamber 110. Sample holder 120 may be configured to rotate (as indicated by arrows ‘x’ and ‘y’) around at least one axis ‘x’ and ‘y’, for example, using manipulator 128. Sample holder 120 may include a heating element (not illustrated) configured to heat a sample attached to holder 120. Sample holder 120 may be connected to beam-equivalent pressure (BEP) ionizing gauges 125 for measuring fluxes from effusion cells 130 and 135.

Effusion cells 130 and 135 may include cells for evaporation or sublimation of solid material to create beams of atoms of individual elements/compounds in an ultrahigh vacuum (UHV). The beams generated in effusion cells 130 and 135 are directed toward the substrate 120 surface where the solidification occurs. In a nonlimiting example, effusion cells 130 and 135 may be used for the generation of the As flux, the In flux, and the Eu flux. In some embodiments, each one of effusion cells 130 and 135 may include a shutter 138 for controlling the addition of the flux from the effusion cell.

System 100 may further include a reflection high-energy electron diffraction (RHEED) gun 140 and a fluorescence screen 150. RHEED gun 140 and fluorescence screen 150 may be included in an RHEED system for characterizing the surface of the sample in chamber 110.

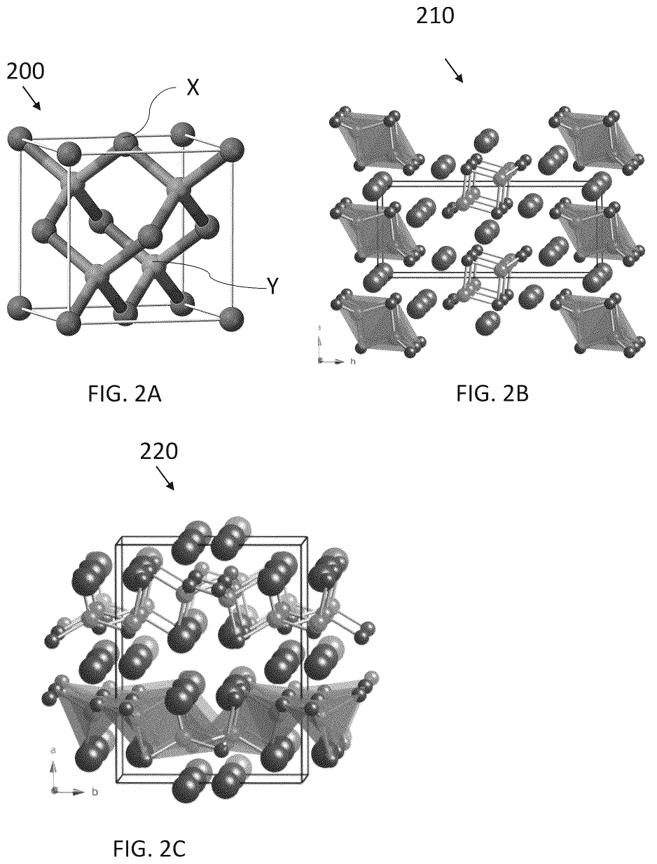

Reference is now made to FIGS. 2A, 2B, and 2C which are illustrations of crystal structures (e.g., unit cells) of InAs, Eu₃In₂As₄, and Ba₃In₂As₄ according to some embodiments of the invention. The InAs unit cell 200 illustrated in FIG. 2A is representative of all YZ Wurtzite crystal structures according to some embodiments of the invention. The YZ Wurtzite crystal structure is the structure of the target nanowire which is the phase from which the X₃Y₂Z₄ ternary Zintl phase is grown using the solid-state conversion topotactic process discussed herein and illustrated in FIG. 1A.

In some embodiments, the X₃Y₂Z₄ ternary Zintl phase may be fabricated by the method of FIG. 1B, for example, using MBE system 100.

In some embodiments, X is selected from Eu, Ca, Sr, and Ba; Y is In; and Z is As. For example, the X₃Y₂Z₄ ternary Zintl phase may be the Eu₃In₂As₄ or Sr₃In₂As₄ crystal structure 210, illustrated in FIG. 2B or Ba₃In₂As₄ crystal structure 220 illustrated in FIG. 2C. In some embodiments, X is selected from Eu, Sr, and Ba; Y is In; and Z is P. For example, the X₃Y₂Z₄ ternary Zintl phase may be Sr₃In₂P₄. In some embodiments, all of these X₃Y₂Z₄ ternary Zintl phases may have a Pnnm space group.

In some embodiments, X is Ba; Y is Al; and Z is As or P. For example, the X₃Y₂Z₄ ternary Zintl phase may be Ba₃Al₂As₄. In some embodiments, all of these X₃Y₂Z₄ ternary Zintl phases may have a Pnma space group.

In some embodiments, the X₃Y₂Z₄ ternary Zintl phase may have a crystal structure which include subgroups of the orthorhombic crystal.

In some embodiments, the Y and Z atoms in the X₃Y₂Z₄ ternary Zintl phase form an anionic lattice, while the X forms the cationic structure. In some embodiments, the Z atoms (e.g., In and P) may occupy positions of a hexagonal lattice, similar to the positions of these atoms in the target YZ Wurtzite crystal structure. Thereby, the Z atoms may be regarded as the skeleton for the bi-directional solid state diffusion of the In and Eu atoms.

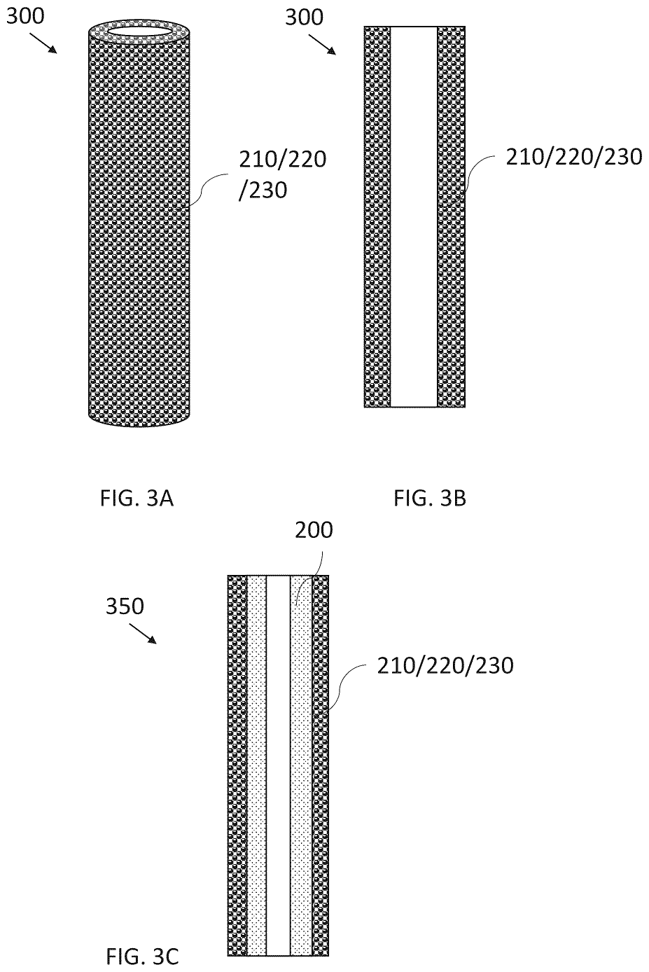

Reference is now made to FIGS. 3A and 3B which are illustrations of a side view and a cross-section view of a nanowire according to embodiments of the invention. In some embodiments, nanowire 300 may include the ternary Zintl phase of the stoichiometric formula of X₃Y₂Z₄, discussed herein above. In some embodiments, nanowire 300 may be fabricated by the method of FIG. 1B, for example, using MBE system 100.

In some embodiments, the entire nanowire 300 may be a single crystal of the X₃Y₂Z₄ ternary Zintl. For example, nanowire 300 may include a single crystal of structure 210 (illustrated in FIG. 2B), a single crystal of structure 220 (illustrated in FIG. 2C) or a single crystal of structure 230 (illustrated in FIG. 2C).

In some embodiments, nanowire 300 may have a length of between 1 to 10 μm, for example, between 1 to 2 μm, 1 to 4 μm, 2 to 6 μm, 4 to 8 μm, 5 to 10 μm or any value or range therebetween.

In some embodiments, nanowire 300 may have a diameter of between 10 to 200 nm, for example, between 10 to 50 nm, 20 to 80 nm, 40 to 100 nm, 80 to 150 nm, 120 to 180, 100 to 200 nm, or any value or range therebetween.

In some embodiments, the nanowire may have a core-shell structure, the core-shell nanowire comprises a core in contact with a shell, and wherein the shell consists essentially of said ternary Zintl phase, as illustrated and discussed with respect to FIG. 3C.

Reference is now made to FIG. 3C which is an illustration of another nanowire according to some embodiments of the invention. In some embodiments, a nanowire 350 may have a core-shell structure comprising a core having the Wurtzite crystal structure and a shell comprising the ternary Zintl phase of the stoichiometric formula of X₃Y₂Z₄. In some embodiments, the core is InAs, and X is selected from Eu, Ca, Sr, or Ba, Y is In, and Z is As. In some embodiments, the core is InP, and X is selected from Eu, Sr, or Ba, Y is In, and Z is P. In some embodiments, the core is AlAs, and X is Ba, Y is Al and Z is As. In some embodiments, the core is AIP and X is Ba, Y is Al and Z is P. In some embodiments, nanowire 350 may have a semiconducting core and a magnetic shell.

For example, nanowire 350 may have a core of a structure 200 comprising InAs and shell having crystal structure 220. In another example, nanowire 350 may have a core of structure 200 comprising InP and shell having crystal structure 230. In yet another example, nanowire 350 may have a core of structure 200 comprising AlAs and shell having crystal structure 230.

In some embodiments, nanowire 350 may be fabricated by the method of FIG. 1B, for example, using MBE system 100.

In some embodiments, nanowire 350 may have a length of between 1 to 10 μm, for example, between 1 to 2 μm, 1 to 4 μm, 2 to 6 μm, 4 to 8 μm, 5 to 10 μm or any value or range therebetween.

In some embodiments, the shell is 1 monolayer or more, for example, 2, 3, 4, 5, 10, 15, 20, 50, 100, 150, 200, 300 monolayers, and any value therebetween.

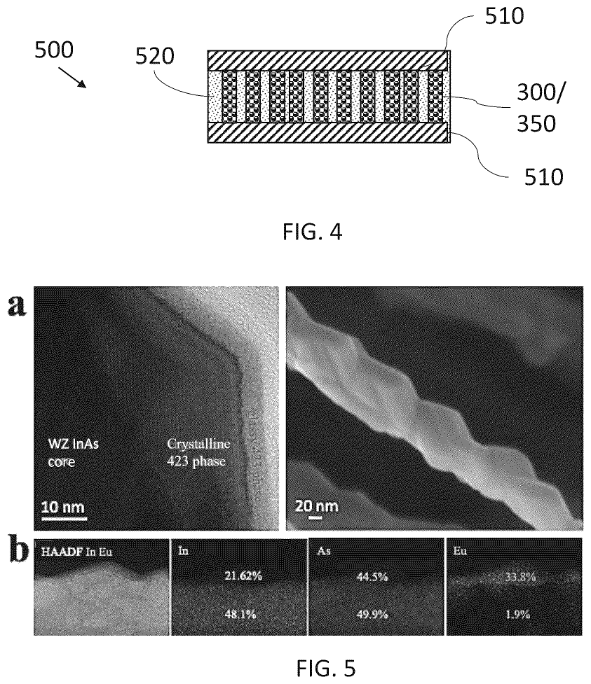

Reference is now made to FIG. 4 which is an illustration of a device according to some embodiments of the invention. Device 500 may include one or more nanowires according to any one of the embodiments disclosed herein above, for example, nanowires, 300 or 350; and two conductive layers 510 sandwiching said one or more nanowires. In some embodiments, one or more nanowires 300 or 350 are arranged such that the longitudinal direction of each nanowire is substantially perpendicular to the surface of each conductive layer 510. Alternatively, one or more nanowires 300 or 350 are arranged such that the longitudinal direction of each nanowire is tilted at 35° with respect to the surface of each conductive layer 510.

In some embodiments, when the one or more nanowires are nanowires 350, device 500 may include nanowires comprising both a semiconducting core (e.g., InAs) and a magnetic shell (e.g., Eu₃In₂As₄).

In some embodiments, device 500 may further include a dielectric material 520 encompassing the one or more nanowire while filling a volume between the two conductive layers.

### EXAMPLES

Eu₃In₂As₄ nanowire was grown on an InAs nanowire using the topotactic conversion process discussed herein above with respect to FIGS. 1A, 1B using the system discussed with respect to FIG. 1C. Nanowires comprising the Eu₃In₂As₄ were investigated using several characterization methods.

Reference is now made to FIG. 5 which shows transmission electron microscopy (TEM) images (a) and high-angle annular dark-field imaging (HAADF) of the In and Eu in the crystal and energy-dispersive X-ray spectroscopy (EDS) of Eu₃In₂As₄ crystals on InAs core according to some embodiments of the invention. As clearly shown in the TEM image and verified by the EDS, a full conversion of the InAs phase into the Eu₃In₂As₄ crystal was demonstrated. Terminating the process prior to achieving full conversion may allow producing the core-shell nanowires 350 discussed with respect to FIG. 3C. Controlling parameters of the growth, such as, temperature and time, may allow controlling the thickness of the grown Eu₃In₂AS₄ shell.

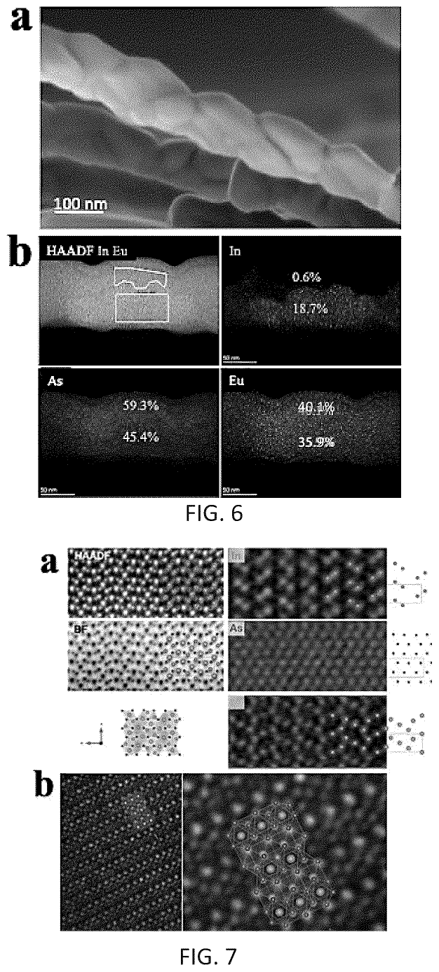

Reference is now made to FIG. 6 showing scanning electron microscopy (SEM) image (a) and EDS images (b) of a fully converted nanowire comprising only the Eu₃In₂As₄ crystal with an external shell of Eu₂As₃. As shown in FIG. 6, all the InAs crystal was converted into the Eu₃In₂As₄ phase.

Reference is now made to FIG. 9 which shows lattice images simulated from TEM-EDS images of the Eu₃In₂As₄ (a) and the Eu₃In₂As₄ lattice structure overlaid with a HAADF image (b) according to some embodiments of the invention. As shown in all the images, a good match was found for all atoms in the Eu₃In₂As₄ crystal.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. A nanowire, comprising:
a ternary Zintl phase of a stoichiometric formula of X₃Y₂Z₄, wherein the ternary Zintl phase is in a crystalline state; and wherein:
X is selected from Eu, Ca, Sr, and Ba;
Y is In or Al; and
Z is As or P.

2. The nanowire of claim 1, wherein
(i) X is selected from Eu, Ca, Sr, and Ba; Y is In; and Z is As; or
(ii) X is selected from Eu, Sr, and Ba; Y is In; and Z is P.

3. The nanowire of claim 1, wherein said ternary Zintl phase has a Pnnm space group.

4. The nanowire of claim 1, wherein X is Ba; Y is Al; and Z is As or P.

5. The nanowire of claim 4, wherein said ternary Zintl phase has a Pnma space group.

6. The nanowire of claim 1, wherein the X₃ Y₂Z₄ ternary Zintl phase has a crystal structure which includes subgroups of an orthorhombic crystal.

7. The nanowire of claim 6, wherein said Y and Z form an anionic lattice.

8. The nanowire of claim 1, wherein Z occupies positions of a hexagonal lattice.

9. The nanowire of claim 1, characterized by a length of between 1 to 10 μm.

10. The nanowire of claim 1, characterized by a diameter of between 10 to 200 nm.

11. The nanowire of claim 1, characterized by a core-shell structure, said core-shell structure comprises a shell, said shell consists essentially of said ternary Zintl phase.

12. The nanowire of claim 11, wherein said core consists a crystalline material of formula YZ, having a Wurtzite crystal structure.

13. A nanowire, comprising:
a core having a Wurtzite crystal structure; and
a shell comprising a ternary Zintl phase of a stoichiometric formula of X₃Y₂Z₄, wherein:
a. the core is InAs, and X is selected from Eu, Ca, Sr, or Ba, Y is In, and Z is As;
b. the core is InP, and X is selected from Eu, Sr, or Ba, Y is In, and Z is P;
c. the core is AlAs, and X is Ba, Y is Al and Z is As; or
d. the core is AIP and X is Ba, Y is Al and Z is P.

14. The nanowire of claim 13, characterized by a length of between 1 to 10 μm.

15. The nanowire of claim 13, characterized by a diameter of between 10 to 200 nm.

16. The nanowire of claim 13, wherein said shell is a monolayer.

17. The nanowire of claim 13, wherein said shell comprises two or more monolayers.

18. A device, comprising a nanowire
the nanowire comprising:
a ternary Zintl phase of a stoichiometric formula of X₃Y₂Z₄, wherein the ternary Zintl phase is in a crystalline state; and wherein:
X is selected from Eu, Ca, Sr, and Ba;
Y is In or Al; and
Z is As or P.

19. The device of claim 18, comprising two conductive layers sandwiching said nanowire,
wherein said nanowire is arranged at one of:
a. the longitudinal direction of said nanowire is substantially perpendicular to the surface of each conductive layer of said two conductive layers; or
b. the longitudinal direction of said nanowire is tilted at 35° with respect to the surface of each conductive layer of said two conductive layers.

20. The device of claim 18, further comprising a dielectric material encompassing said nanowire while filling a volume between said two conductive layers.

21.-23 (canceled)
